(19) United States
(12) Patent Application Publication
(10) Pub. No.: US 2023/0134317 A1
(43) Pub. Date: May 4, 2023

(54) ELECTRICAL CONNECTION STRUCTURE AND ELECTRONIC DEVICE INCLUDING THE SAME

(71) Applicant: Innolux Corporation, Miaoli County (TW)

(72) Inventors: Hao-Jung Huang, Miao-Li County (TW); Chia-Chun Liu, Miao-Li County (TW)

(73) Assignee: Innolux Corporation, Miaoli County (TW)

(21) Appl. No.: 17/958,452

(22) Filed: Oct. 3, 2022

Related U.S. Application Data
(60) Provisional application No. 63/275,893, filed on Nov. 4, 2021.

(30) Foreign Application Priority Data
Jul. 27, 2022 (CN) 202210891522.X

(51) Int. Cl. H01L 23/538

(52) U.S. Cl. CPC H01L 23/5385; H01L 25/167

(57) ABSTRACT

Disclosed are an electrical connection structure and an electronic device including the same. The electrical connection structure includes a first substrate, a first conductive pad, a second substrate, a second conductive pad, a through hole, and a conductive material is provided. The first conductive pad is disposed on the first substrate. The first conductive pad includes a first upper surface. The second conductive pad is disposed on the second substrate. The second conductive pad includes a second upper surface. The through hole penetrates the first substrate and exposes a part of the second upper surface. The conductive material is partially disposed in the through hole. The conductive material includes a narrowest portion and a first contact portion in contact with the second upper surface. A length of the first contact portion is greater than a length of the narrowest portion in a cross-sectional view.

### CROSS-REFERENCE TO RELATED APPLICATION

This application claims the priority benefits of U.S. application Ser. No. 63/275,893, filed on Nov. 4, 2021 and Chinese application no. 202210891522.X, filed on Jul. 27, 2022. The entirety of each of the above-mentioned patent applications is hereby incorporated by reference herein and made a part of this specification.

### BACKGROUND

### Technical Field

The disclosure relates to a connection structure, and particularly relates to an electrical connection structure and an electronic device including the same.

### Description of Related Art

Along with continuous expansion of applications and innovative technological development of electronic devices, requirements for an electrical connection structure and quality of the electronic devices are increasing so that the electronic devices are faced with different issues. Therefore, continuous update and adjustment for research and development of electronic devices may be required.

### SUMMARY

The disclosure is directed to an electrical connection structure and an electronic device including the same.

According to an embodiment of the disclosure, an electrical connection structure includes a first substrate, a first conductive pad, a second substrate, a second conductive pad, a through hole, and a conductive material. The first conductive pad is disposed on the first substrate. The first conductive pad includes a first upper surface. The second conductive pad is disposed on the second substrate. The second conductive pad includes a second upper surface. The through hole penetrates the first substrate and exposes a part of the second upper surface. The conductive material is partially disposed in the through hole. The conductive material includes a narrowest portion and a first contact portion in contact with the second upper surface. A length of the first contact portion is greater than a length of the narrowest portion in a cross-sectional view.

According to an embodiment of the disclosure, an electronic device includes an electrical connection structure, an electronic component, a driving substrate; and a third conductive pad. The electrical connection structure includes a first substrate, a first conductive pad, a second substrate, a second conductive pad, a through hole, and a conductive material. The first conductive pad is disposed on the first substrate. The first conductive pad includes a first upper surface. The second conductive pad is disposed on the second substrate. The second conductive pad includes a second upper surface. The through hole penetrates the first substrate and exposes a part of the second upper surface. The conductive material is partially disposed in the through hole. The conductive material includes a narrowest portion and a first contact portion in contact with the second upper surface. A length of the first contact portion is greater than a length of the narrowest portion in a cross-sectional view. The electronic component is disposed on the first substrate, and electrically connected to the first conductive pad disposed on the first substrate. The third conductive pad is disposed on the driving substrate, and electrically connected to the second substrate.

Based on the above description, in the embodiments of the disclosure, the through hole penetrates the first substrate and exposes a part of the second upper surface of the second conductive pad, and the conductive material is partially disposed in the through hole, so that the first substrate and the second substrate have an electrical conduction path. Therefore, the electrical connection structure of the disclosure may achieve the effect of electrically connecting a plurality of substrates, and when it is subsequently applied to an electronic device, the electrical conduction path between the substrates may be shortened and a design of a peripheral region may be simplified, so as to achieve a slim border design of the electronic device. In addition, the conductive material includes the narrowest portion and the first contact portion in contact with the second upper surface. In a cross-sectional view, the length of the first contact portion is greater than the length of the narrowest portion, which increases a contact length between the conductive pad and the conductive material, and enhances a success rate of electrical connection of multiple substrates, so that the electrical connection structure of the disclosure may have better electrical reliability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of an electrical connection structure according to an embodiment of the disclosure.

FIG. 2 is a schematic cross-sectional view of an electrical connection structure according to another embodiment of the disclosure.

FIG. 3 is a schematic cross-sectional view of an electrical connection structure according to another embodiment of the disclosure.

FIG. 4 is a schematic cross-sectional view of an electrical connection structure according to another embodiment of the disclosure.

FIG. 5 is a schematic cross-sectional view of an electrical connection structure according to another embodiment of the disclosure.

FIG. 6 is a schematic cross-sectional view of an electrical connection structure according to another embodiment of the disclosure.

FIG. 7 is a schematic cross-sectional view of an electrical connection structure according to another embodiment of the disclosure.

FIG. 8 is a schematic cross-sectional view of an electrical connection structure according to another embodiment of the disclosure.

FIG. 9 is a schematic cross-sectional view of an electrical connection structure according to another embodiment of the disclosure.

FIG. 10 is a schematic cross-sectional view of an electronic device using the electrical connection structure of FIG. 1.

### DESCRIPTION OF THE EMBODIMENTS

The disclosure may be understood by referring to the following detailed description in conjunction with the accompanying drawings. It should be noted that, in order to facilitate readers' understanding and to simplify the drawings, the drawings in the disclosure only depict a part of an electronic device, and specific elements in the drawings are not drawn according to actual scale. In addition, the number and size of each element in the figures are for illustration only, and are not intended to limit a scope of the disclosure.

Throughout the specification and the appended claims of the disclosure, certain terms may be used to refer to specific elements. Those skilled in the art will understand that electronic device manufacturers may refer to the same element by different names. This document does not intend to distinguish between elements that have the same function but have different names.

In the following description and claims, the words “comprising” and “including” are open-ended words, so they should be interpreted as meaning “including but not limited to . . . ”.

In addition, relative terms, such as “below” or “bottom” and “above” or “top,” may be used in the embodiments to describe a relative relationship of one element of the drawings to another element. It will be understood that if a device in the figures is turned upside down, elements described on a “lower” side would become elements described on an “upper” side.

In some embodiments of the disclosure, terms related to bonding and connection, such as “connect”, “interconnect”, etc., unless otherwise defined, may refer to that two structures are in direct contact, or may also refer to that the two structures are not directly (indirectly) in contact with each other, and there are other structures between the two structures. And the terms of joining and connecting may also include the case where both structures are movable, or both structures are fixed. Furthermore, a term “couple” includes transfer of energy between two structures by means of direct or indirect electrical connection, or transfer of energy between two separate structures by means of mutual induction.

It will be understood that when an element or a film layer is referred to as being “on” or “connected to” another element or film layer, it may be directly on or directly connected to the other element or film layer, or there are intervening elements or film layers there between (indirect case). In contrast, when an element is referred to as being “directly on” or “directly connected to” another element or film layer, there are no intervening elements or film layers there between.

In the disclosure, lengths, widths, thicknesses, heights or areas, or a distance or spacing between components may be measured by using an optical microscope (OM), a scanning electron microscope (SEM), a film thickness profiler (α-step), an ellipsometer, or other suitable methods. In detail, according to some embodiments, the scanning electron microscope may be used to obtain cross-sectional structure images of the components to be measured, and measure a length, a width, a thickness, a height or an area of each component, or a distance or spacing between components, but the disclosure is not limited thereto.

In addition, phrases “a given range is from a first value to a second value”, “a given range falls within a range from the first value to the second value” means that the given range includes the first value, the second value and other values there between. If a first direction is perpendicular to a second direction, an angle between the first direction and the second direction may be between 80 degrees and 100 degrees; if the first direction is parallel to the second direction, the angle between the first direction and the second direction may be between 0 and 10 degrees. The terms “about”, “equal to”, “equal” or “same”, “substantially” or “approximately” are generally construed as within 20% of a given value or range, or construed as within 10%, 5%, 3%, 2%, 1%, or 0.5% of the given value or range.

As used herein, the terms “film” and/or “layer” may refer to any continuous or discontinuous structures and materials (such as materials deposited by the methods disclosed herein). For example, films and/or layers may include two-dimensional materials, three-dimensional materials, nanoparticles, or even partial or complete molecular layers, or partial or complete atomic layers, or atom and/or molecular clusters. The film or layer may comprise a material or layer having pinholes, which may be at least partially continuous.

Although the terms first, second, third . . . may be used to describe various constituent elements, the constituent elements are not limited by the terms. These terms are only used to distinguish a single constituent element from other constituent elements in the specification.

The same terms may not be used in the claims, but replaced by first, second, third, . . . in the order in which the elements are recited in the claims. Therefore, in the following description, the first constituent element may be the second constituent element in the claims.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should be noted that, in the following embodiments, the technical features in several different embodiments may be replaced, reorganized, and mixed to complete other embodiments without departing from the spirit of the disclosure.

Reference will now be made in detail to the exemplary embodiments of the disclosure, examples of which are illustrated in the accompanying drawings. Wherever possible, the same reference numerals are used in the drawings and description to refer to the same or like parts.

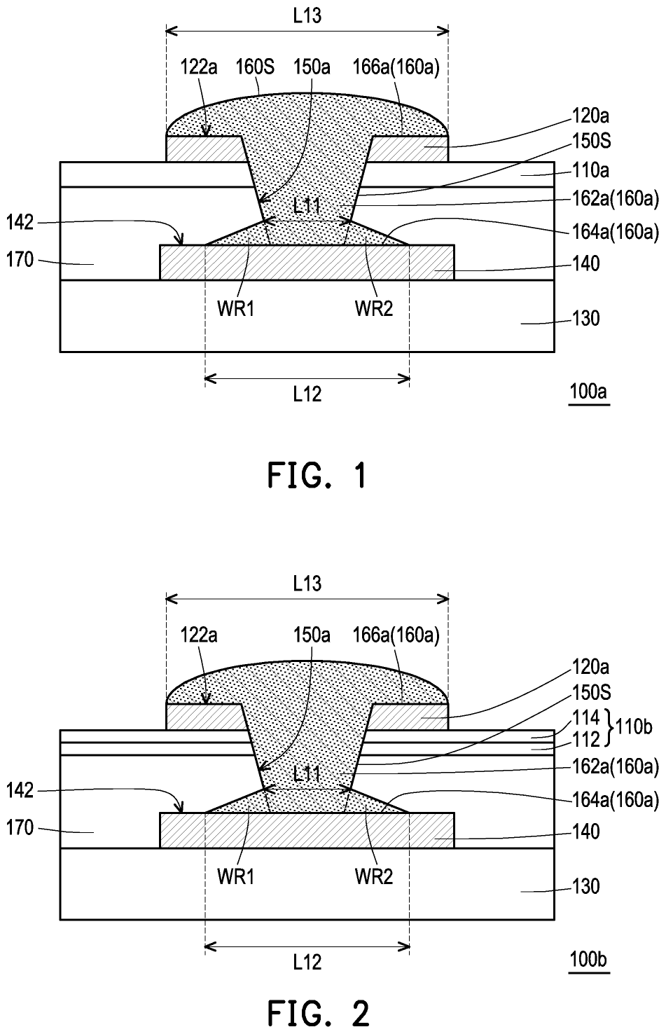

FIG. 1 is a schematic cross-sectional view of an electrical connection structure according to an embodiment of the disclosure. Referring to FIG. 1, in the embodiment, an electrical connection structure 100a includes a first substrate 110a, a first conductive pad 120a, a second substrate 130, a second conductive pad 140, a through hole 150a, and a conductive material 160a. The first conductive pad 120a is disposed on the first substrate 110a, where the first conductive pad 120a includes a first upper surface 122a. The second conductive pad 140 is disposed on the second substrate 130, where the second conductive pad 140 includes a second upper surface 142. The through hole 150a penetrates the first substrate 110a and exposes a part of the second upper surface 142. The conductive material 160a is partially disposed in the through hole 150a, where the conductive material 160a includes a narrowest portion 162a and a first contact portion 164a in contact with the second upper surface 142. In a cross-sectional view, a length L12 of the first contact portion 164a is greater than a length L11 of the narrowest portion 162a, which may increase a contact length between the second conductive pad 140 and the conductive material 160a, and improve a success rate of electrical connection between the first substrate 110a and the second substrate 130. In the embodiment, the through hole 150a substantially has a design of a wide top and a narrow bottom, but in order to avoid insufficient contact length between the conductive material 160a and the second conductive pad 140, the through hole 150a of FIG. 1 may include a design of a through hole wide portion WR1 and a through hole wide portion WR2 at left and right sides. In a direction from the narrowest portion 162a to the first contact portion 164a, the through hole wide portion WR1 and the through hole wide portion WR2 include portions where a through hole diameter on the left and right sides of the through hole 150a gradually increases, and the through hole wide portion WR1 and the through hole wide portion WR2 are adjacent to the second conductive pad 140. When the conductive material 160a fills the through hole wide portion WR1 and the through hole wide portion WR2, the contact length between the second conductive pad 140 and the conductive material 160a may be increased, and the success rate of the electrical connection between the first substrate 110a and the second substrate 130 may also be improved. In some embodiments, the design of the through hole 150a may include one of the through hole wide portion WR1 and the through hole wide portion WR2. When the conductive material 160a fills one of the through hole wide portion WR1 and the through hole wide portion WR2, the contact length of the second conductive pad 140 and the conductive material 160a may also be improved, and the success rate of the electrical connection between the first substrate 110a and the second substrate 130 may be improved.

The manner in which the conductive material 160a is disposed in the through hole 150a may include solder paste printing, inkjet printing, chemical vapor deposition, physical vapor deposition, electroplating, or other suitable methods, or a combination of the above methods, but the disclosure is not limited thereto. A material of the conductive material 160a may include tantalum (Ta), niobium (Nb), hafnium (HO, nickel (Ni), chromium (Cr), cobalt (Co), zirconium (zirconium, Zr), tungsten (W), aluminum (Al), tin (Sn), copper (Cu), silver (Ag), aurum (Au) or other suitable metals, or alloys or combinations of the above materials, but the disclosure is not limited thereto. The through hole 150a may be fabricated by, for example, mechanical drilling, laser drilling, ultrasonic drilling, micro electrical discharge machining (μ-EDM), micro powder blasting or inductively coupled plasma reactive ion etching (ICP-RIE) or other suitable methods, or a combination of the above methods, but the disclosure is not limited thereto.

In detail, in the embodiment, the first substrate 110a and the second substrate 130 may be, for example, respectively rigid substrates, flexible substrates, or a combination thereof. A material of the first substrate 110a and a material of the second substrate 130 may be, for example, glass, quartz, sapphire, ceramic, polycarbonate (PC), polyimide (PI), polyethylene terephthalate (PET), other suitable substrate materials, or a combination of the above materials, but the disclosure is not limited thereto. Furthermore, as shown in FIG. 1, the electrical connection structure 100a of the embodiment further includes an intermediate layer 170 disposed between the first substrate 110a and the second substrate 130 and covering the second conductive pad 140. The through hole 150a penetrates the first substrate 110a and a part of the intermediate layer 170 to expose a part of the second upper surface 142. In other words, the intermediate layer 170 may be disposed between at least two of a plurality of substrates. A material of the intermediate layer 170 may include organic materials, inorganic materials, other suitable substrate materials, or a combination of the above materials, but the disclosure is not limited thereto. In some embodiments, the intermediate layer 170 may adhere at least two of the plurality of substrates.

Referring to FIG. 1 again, in the embodiment, the through hole 150a penetrates the first conductive pad 120a, the first substrate 110a and a part of the intermediate layer 170 to expose a part of the second upper surface 142 of the second conductive pad 140. A diameter of the through hole 150a may be, for example, gradually reduced first and then gradually enlarged in a direction from the first substrate 110a toward the second upper surface 142, but the disclosure is not limited thereto. The narrowest portion 162a may be located in the intermediate layer 170, but the disclosure is not limited thereto. The conductive material 160a fills the through hole 150a and extends to the first upper surface 122a of the first conductive pad 120a located on both sides of the through hole 150a, where the filled conductive material 160a electrically connects the first conductive pad 120a and the second conductive pad 140, which achieves an effect of vertically conducting (i.e., electrically connecting) the first substrate 110a and the second substrate 130.

Furthermore, the conductive material 160a of the embodiment further includes a second contact portion 166a in contact with the first upper surface 122a, where a length L13 of the second contact portion 166a is greater than the length L11 of the narrowest portion 162a, which may increase a contact length between the first conductive pad 120a and the conductive material 160a, and improve the success rate of electrical connection between the first substrate 110a and the second substrate 130. As shown in FIG. 1, the length L13 of the second contact portion 166a in the embodiment is greater than the length L12 of the first contact portion 164a, and the length L12 of the first contact portion 164a is greater than the length L11 of the narrowest portion 162a, which may increase the contact length between the first conductive pad 120a and the conductive material 160a and the contact length between the second conductive pad 140 and the conductive material 160a, and improve the success rate of the electrical connection between the first substrate 110a and the second substrate 130. Furthermore, the conductive material 160a of the embodiment has an arc-shaped upper surface 1605, which may facilitate better sidewall step coverage during film deposition when film deposition is performed on the upper layer of the conductive material 160a.

In brief, the through hole 150a penetrates the first substrate 110a and exposes a part of the second upper surface 142 of the second conductive pad 140, and the conductive material 160a is partially disposed in the through hole 150a, so that the first substrate 110a and the second substrate 130 may be electrically conducted. Therefore, the electrical connection structure 100a of the embodiment may achieve the effect of electrically connecting a plurality of substrates, and when the electrical connection structure 100a is subsequently applied to an electronic device, an electrical conduction path between the first substrate 110a and the second substrate 130 may be greatly shortened, the design of the peripheral regions of the first substrate 110a and the second substrate 130 may also be simplified, and the electronic device may achieve a design of slim border or even no border. In addition, in a cross-sectional view, the length L12 of the first contact portion 164a of the conductive material 160a is greater than the length L11 of the narrowest portion 162a of the conductive material 160a, and the through hole 150a may be designed to include the through hole wide portion WR1 and/or the through hole wide portion WR2, when the conductive material 160a fills the through hole wide portion WR1 and/or the through hole wide portion WR2, the contact length between the second conductive pad 140 and the conductive material 160a may be increased, and the success rate of the electrical connection between the first substrate 110a and the second substrate 130 may also be improved, so that the electrical connection structure 100a of the disclosure may have better electrical reliability.

It should be noted here that the following embodiments adopt the element numbers and a part of the contents of the previous embodiments, where the same numbers are used to represent the same or similar elements, and the description of the same technical contents is omitted. For the description of the omitted part, reference may be made to the foregoing embodiments, and repeated descriptions thereof in the following embodiments will not be repeated.

FIG. 2 is a schematic cross-sectional view of an electrical connection structure according to another embodiment of the disclosure. Referring to FIG. 1 and FIG. 2 at the same time, an electrical connection structure 100b is similar to the electrical connection structure 100a of FIG. 1, and descriptions of similar parts thereof are not repeated here. A difference between FIG. 1 and FIG. 2 is: in the embodiment of FIG. 2, a first substrate 110b includes a base layer 112 and a dielectric layer 114, where the dielectric layer 114 is disposed on the base layer 112, and the first conductive pad 120a is disposed on the dielectric layer 114. A material of the base layer 112 is, for example, a polymer, and a material of the dielectric layer 114 is, for example, an inorganic material, but the disclosure is not limited thereto. In some embodiments, a multi-layer stacked structure (not shown) may be designed between the base layer 112 and the first conductive pad 120a, for example, a conductive layer, a semiconductor layer, an insulating layer, a passivation layer, a light-emitting layer, an encapsulation layer or other suitable stacked layers, or a combination of the above stacked layers may be added there between, but the disclosure is not limited thereto.

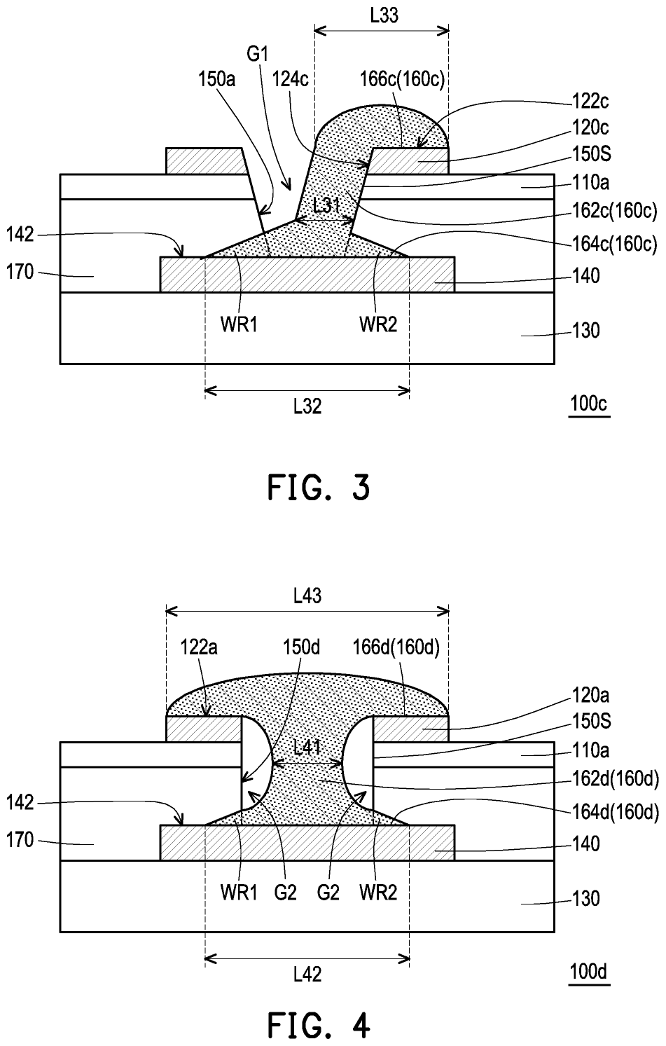

FIG. 3 is a schematic cross-sectional view of an electrical connection structure according to another embodiment of the disclosure. Referring to FIG. 1 and FIG. 3 at the same time, an electrical connection structure 100c is similar to the electrical connection structure 100a of FIG. 1, and descriptions of similar parts thereof are not repeated here. A difference between FIG. 1 and FIG. 3 is that in the embodiment of FIG. 3, an air gap G1 is between a conductive material 160c and the through hole 150a, i.e., the conductive material 160c fills the through hole wide portion WR1 and the through hole wide portion WR2 but not completely fill the through hole 150a. In detail, in the embodiment, a first conductive pad 120c includes a side surface 124c, where the side surface 124c is adjacent to the through hole 150a. The conductive material 160c fills the through hole 150a and extends along the side surface 124c of the first conductive pad 120c to a first upper surface 122c of the first conductive pad 120c. The conductive material 160c includes a narrowest portion 162c, a first contact portion 164c in contact with the second upper surface 142, and a second contact portion 166c in contact with the first upper surface 122c, where a length L33 of the second contact portion 166c is greater than a length L31 of the narrowest portion 162c, and a length L32 of the first contact portion 164c is greater than the length L31 of the narrowest portion 162c, which may increase a contact length of the first conductive pad 120c, the second conductive pad 140 and the conductive material 160a, and improve a success rate of electrical connection between the first substrate 110a and the second substrate 130. In the embodiment of FIG. 3, the length L32 of the first contact portion 164c may be greater than the length L33 of the second contact portion 166c. Here, the conductive material 160c fills the through hole wide portion WR1 and the through hole wide portion WR2 and is in direct contact with the second conductive pad 140, the side surface 124c and the first upper surface 122c of the first conductive pad 120c, where the filled conductive material 160c is electrically connected to the first conductive pad 120c and the second conductive pad 140, so as to achieve the effect of vertically conducting (i.e., electrically connecting) the first substrate 110a and the second substrate 130. The electrical connection structure 100c of the embodiment may achieve the effect of electrically connecting a plurality of substrates, and when the electrical connection structure 100c is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border.

In some embodiments, the design of the through hole 150a may include one of the through hole wide portion WR1 and the through hole wide portion WR2, and when the conductive material 160c fills one of the through hole wide portion WR1 and the through hole wide portion WR2, the contact length between the second conductive pad 140 and the conductive material 160c may also be increased to improve the success rate of electrical connection between the first substrate 110a and the second substrate 130.

FIG. 4 is a schematic cross-sectional view of an electrical connection structure according to another embodiment of the disclosure. Referring to FIG. 1 and FIG. 4 at the same time, an electrical connection structure 100d is similar to the electrical connection structure 100a of FIG. 1, and descriptions of similar parts thereof are not repeated here. One of the differences between FIG. 1 and FIG. 4 is that in FIG. 4 of the embodiment, an air gap G2 is between a conductive material 160d and a through hole 150d, i.e., the conductive material 160d fills the through hole wide portion WR1 and the through hole wide portion WR2 but does not completely fill the through hole 150d. In detail, the conductive material 160d is filled into the through hole 150d, and the conductive material 160d includes a narrowest portion 162d, a first contact portion 164d in contact with the second upper surface 142, and a second contact portion 166d in contact with the first upper surface 122a, where a length L43 of the second contact portion 166d is greater than a length L42 of the first contact portion 164d, and the length L42 of the first contact portion 164d is greater than a length L41 of the narrowest portion 162d, so that the contact length between the first conductive pad 120a, the second conductive pad 140 and the conductive material 160d may be increased to improve the success rate of the electrical connection between the first substrate 110a and the second substrate 130. Here, the filled conductive material 160d is electrically connected to the first conductive pad 120a and the second conductive pad 140, so as to achieve the effect of vertically conducting (i.e., electrically connecting) the first substrate 110a and the second substrate 130. The electrical connection structure 100d of the embodiment may achieve the effect of electrically connecting a plurality of substrates, and when the electrical connection structure 100d is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border.

Moreover, the design of the through hole 150d in FIG. 4 may have a relatively uniform through hole diameter at the beginning, and then further include the through hole wide portion WR1 and the through hole wide portion WR2 at a place adjacent to the second upper surface 142. In some embodiments, the design of the through hole 150d may include one of the through hole wide portion WR1 and the through hole wide portion WR2, and when the conductive material 160d fills one of the through hole wide portion WR1 and the through hole wide portion WR2, the contact length between the second conductive pad 140 and the conductive material 160d may also be improved to enhance the success rate of the electrical connection between the first substrate 110a and the second substrate 130.

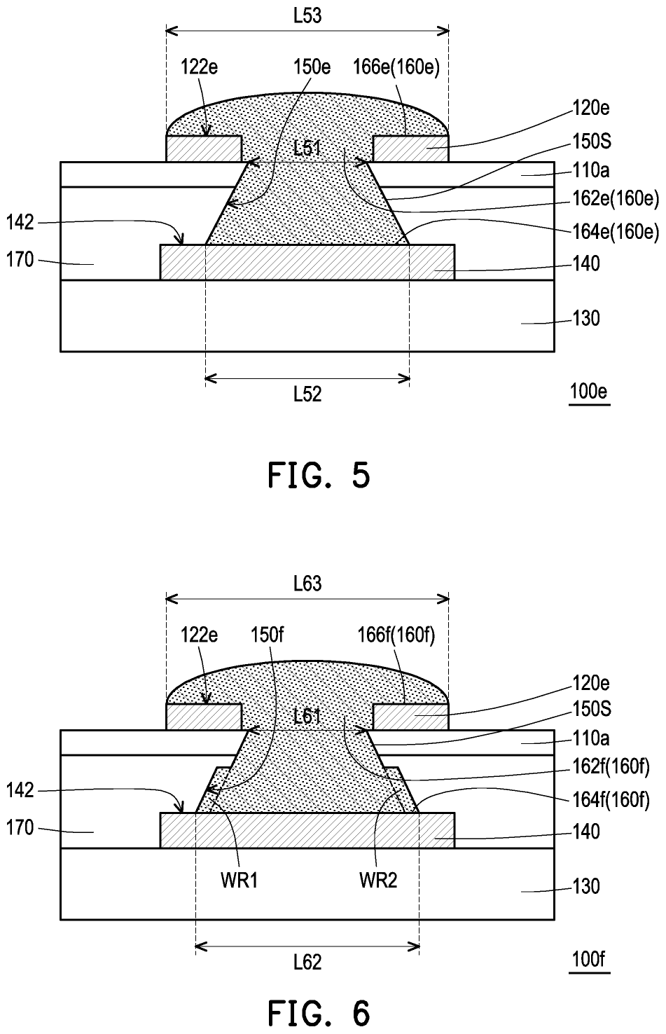

FIG. 5 is a schematic cross-sectional view of an electrical connection structure according to another embodiment of the disclosure. Referring to FIG. 1 and FIG. 5 at the same time, an electrical connection structure 100e is similar to the electrical connection structure 100a of FIG. 1, and similar part thereof are will not be repeated here. A difference between FIG. 1 and FIG. 5 is that in the embodiment in FIG. 5, a through hole 150e is generally narrow at the top and wide at the bottom, and penetrates a first conductive pad 120e, the first substrate 110a and a part of the intermediate layer 170 to expose a part of the second upper surface 142 of the second conductive pad 140, where a diameter of the through hole 150e gradually increases in a direction from the first substrate 110a toward the second upper surface 142. When the through hole 150e penetrates the first conductive pad 120e, a part of the first substrate 110a is exposed, and a conductive material 160e includes a narrowest portion 162e, a first contact portion 164e in contact with the second upper surface 142, and a second contact portion 166e in contact with a first upper surface 122e, where a length of the narrowest portion 162e is L51, and the length L51 may be substantially a diameter of the through hole 150e corresponding to the upper surface of the first substrate 110a. Furthermore, a length L53 of the second contact portion 166e is greater than a length L52 of the first contact portion 164e, and the length L52 of the first contact portion 164e is greater than the length L51 of the narrowest portion 162e, which may increase the contact length between the first conductive pad 120e and the second conductive pad 140 and the conductive material 160e to enhance the success rate of the electrical connection between the first substrate 110a and the second substrate 130. In addition, the filled conductive material 160e electrically connects the first conductive pad 120e and the second conductive pad 140 to achieve the effect of vertically conducting (i.e., electrically connecting) the first substrate 110a and the second substrate 130. The electrical connection structure 100e of the embodiment may achieve the effect of electrically connecting a plurality of substrates, and when the electrical connection structure 100e is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border.

FIG. 6 is a schematic cross-sectional view of an electrical connection structure according to another embodiment of the disclosure. Referring to FIG. 1 and FIG. 6 at the same time, an electrical connection structure 100f is similar to the electrical connection structure 100e of FIG. 5, and descriptions of similar parts thereof are not repeated here. A difference between FIG. 5 and FIG. 6 is that in the embodiment in FIG. 6, a through hole 150f includes the through hole wide portion WR1 and the through hole wide portion WR2. The through hole 150f penetrates the first conductive pad 120e, the first substrate 110a, and a part of the intermediate layer 170 to expose a part of the second upper surface 142 of the second conductive pad 140, where a diameter of the through hole 150f includes the through hole wide portion WR1 and the through hole wide portion WR2, and a shape of the through hole 150f from the first substrate 110a to the second upper surface 142 is like a stepped through hole (increasing gradually in two stages in a stepped manner). A conductive material 160f includes a narrowest portion 162f, a first contact portion 164f in contact with the second upper surface 142, and a second contact portion 166f in contact with the first upper surface 122e, where a length L63 of the second contact portion 166f is greater than a length L62 of the first contact portion 164f, and the length L62 of the first contact portion 164f is greater than a length L61 of the narrowest portion 162f, which may increase the contact length of the first conductive pad 120e, the second conductive pad 140 and the conductive material 160f, and enhance the success rate of electrical connection between the first substrate 110a and the second substrate 130. In addition, the filled conductive material 160f electrically connects the first conductive pad 120e and the second conductive pad 140 to achieve the effect of vertically conducting (i.e., electrically connecting) the first substrate 110a and the second substrate 130. The electrical connection structure 100f of the embodiment may achieve the effect of electrically connecting a plurality of substrates, and when the electrical connection structure 100f is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border. In some embodiments, the design of the through hole 150f may include one of the through hole wide portion WR1 and the through hole wide portion WR2. When the conductive material 160f fills one of the through hole wide portion WR1 and the through hole wide portion WR2, the contact length between the second conductive pad 140 and the conductive material 160f may be increased to enhance the success rate of electrical connection between the first substrate 110a and the second substrate 130.

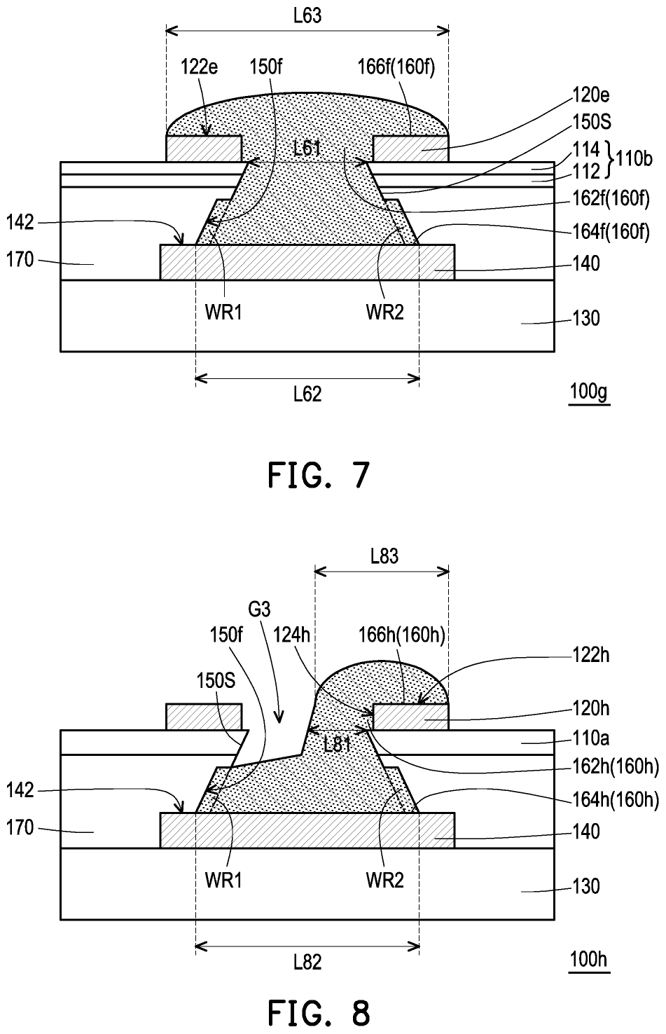

FIG. 7 is a schematic cross-sectional view of an electrical connection structure according to another embodiment of the disclosure. Referring to FIG. 6 and FIG. 7 at the same time, an electrical connection structure 100g is similar to the electrical connection structure 100f of FIG. 6, and descriptions of similar parts thereof are not repeated here. A difference between FIG. 6 and FIG. 7 is that: in the embodiment of FIG. 7, the first substrate 110b includes the base layer 112 and the dielectric layer 114, where the dielectric layer 114 is disposed on the base layer 112, and the first conductive pad 120e is disposed on the dielectric layer 114. A material of the base layer 112 is, for example, a polymer, and a material of the dielectric layer 114 is, for example, an inorganic material, but the disclosure is not limited thereto. In some embodiments, a multi-layer stacked structure (not shown) may be designed between the base layer 112 and the first conductive pad 120e, for example, a conductive layer, a semiconductor layer, an insulating layer, a passivation layer, a light-emitting layer, an encapsulation layer, or other suitable stacked layers, or a combination of the stacked layers may be added there between, but the disclosure is not limited thereto.

FIG. 8 is a schematic cross-sectional view of an electrical connection structure according to another embodiment of the disclosure. Referring to FIG. 6 and FIG. 8 at the same time, an electrical connection structure 100h is similar to the electrical connection structure 100f of FIG. 6, and descriptions of similar parts thereof are not repeated here. A difference between FIG. 6 and FIG. 8 is that: in the embodiment of FIG. 8, an air gap G3 is between a conductive material 160h and the through hole 150f, i.e., the conductive material 160h fills the through hole wide portion WR1 and the through hole wide portion WR2 but does not completely fill the through hole 150f. In detail, in the embodiment, a first conductive pad 120h includes a side surface 124h, where the side surface 124h is adjacent to the through hole 150f. The conductive material 160h is filled into the through hole 150f and extends along the side surface 124h of the first conductive pad 120h to a first upper surface 122h of the first conductive pad 120h. The conductive material 160h includes a narrowest portion 162h, a first contact portion 164h in contact with the second upper surface 142, and a second contact portion 166h in contact with the first upper surface 122h, where a length L83 of the second contact portion 166h is greater than a length L81 of the narrowest portion 162h, and a length L82 of the first contact portion 164h is greater than the length L81 of the narrowest portion 162h, which increases a contact length of the first conductive pad 120h, the second conductive pad 140 and the conductive material 160h, and enhances a success rate of electrical connection between the first substrate 110a and the second substrate 130. In the embodiment of FIG. 8, the length L82 of the first contact portion 164h may be greater than the length L83 of the second contact portion 166h. Here, the conductive material 160h fills the through hole wide portion WR1 and the through hole wide portion WR2 and is in direct contact with the second conductive pad 140, the side surface 124h of the first conductive pad 120h, and the first upper surface 122h, where the filled conductive material 160h electrically connects the first conductive pad 120h and the second conductive pad 140 to achieve the effect of vertically conducting (i.e., electrically connecting) the first substrate 110a and the second substrate 130. The electrical connection structure 100h of the embodiment may achieve the effect of electrically connecting a plurality of substrates, and when the electrical connection structure 100h is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border.

In some embodiments, the design of a through hole 150h may include one of the through hole wide portion WR1 and the through hole wide portion WR2. When the conductive material 160h fills one of the through hole wide portion WR1 and the through hole wide portion WR2, the contact length between the second conductive pad 140 and the conductive material 160h may be increased to enhance the success rate of electrical connection between the first substrate 110a and the second substrate 130.

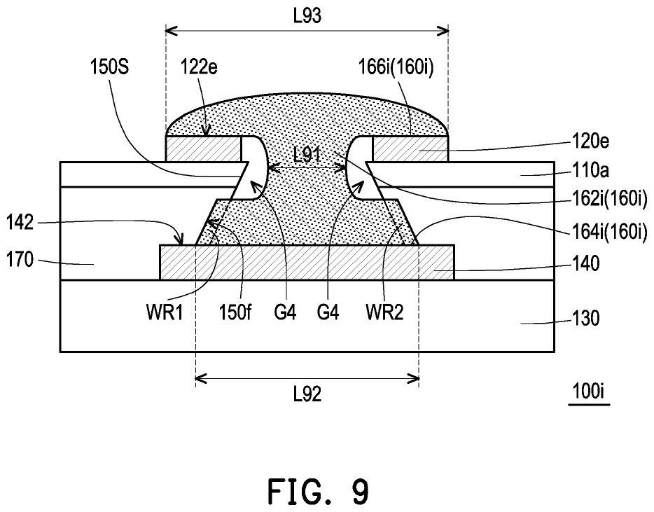

FIG. 9 is a schematic cross-sectional view of an electrical connection structure according to another embodiment of the disclosure. Referring to FIG. 6 and FIG. 9 at the same time, an electrical connection structure 100i is similar to the electrical connection structure 100f of FIG. 6, and descriptions of similar parts thereof are not repeated here. A difference between FIG. 6 and FIG. 9 is that: in the embodiment of FIG. 9, an air gap G4 is between a conductive material 160i and the through hole 150f, i.e., the conductive material 160i fills the through hole wide portion WR1 and the through hole wide portion WR2 but does not completely fill the through hole 150f. In detail, the conductive material 160i is filled into the through hole 150f, and the conductive material 160i includes a narrowest portion 162i, a first contact portion 164i in contact with the second upper surface 142, and a second contact portion 166i in contact with the first upper surface 122e, where a length L93 of the second contact portion 166i is greater than a length L92 of the first contact portion 164i, and the length L92 of the first contact portion 164i is greater than a length L91 of the narrowest portion 162i, which increases a contact length of the first conductive pad 120e, and the second conductive pad 140 with the conductive material 160i to enhance a success rate of electrical connection between the first substrate 110a and the second substrate 130. The filled conductive material 160i electrically connects the first conductive pad 120e and the second conductive pad 140 to achieve the effect of vertically conducting (i.e., electrically connecting) the first substrate 110a and the second substrate 130. The electrical connection structure 100i of the embodiment may achieve the effect of electrically connecting a plurality of substrates, and when the electrical connection structure 100i is subsequently applied to an electronic device, the electrical conduction path between the first substrate 110a and the second substrate 130 may be greatly shortened, the design of the peripheral regions of the first substrate 110a and the second substrate 130 may also be simplified, and the electronic device may achieve a design of slim border or even no border.

In some embodiments, the design of the through hole 150f may include one of the through hole wide portion WR1 and the through hole wide portion WR2. When the conductive material 160i fills one of the through hole wide portion WR1 and the through hole wide portion WR2, the contact length between the second conductive pad 140 and the conductive material 160i may be increased to enhance the success rate of electrical connection between the first substrate 110a and the second substrate 130.

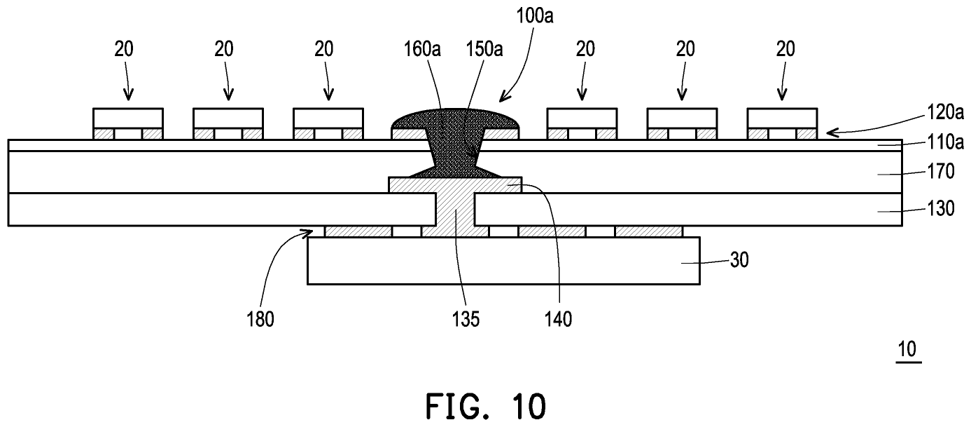

FIG. 10 is a schematic cross-sectional view of an electronic device using the electrical connection structure of FIG. 1. Referring to FIG. 10, in the embodiment, an electronic device 10 includes the electrical connection structure 100a of FIG. 1, an electronic component 20, a driving substrate 30 and a third conductive pad 180, where the second substrate 130 further includes a conductive via 135 electrically connected to the second conductive pad 140. The electronic component 20 is disposed on the first substrate 110a and are electrically connected to the first conductive pad 120a disposed on the first substrate 110a. The third conductive pad 180 is disposed on the driving substrate 30 and is electrically connected to the conductive via 135 of the second substrate 130. In other words, the electronic device 10 of the embodiment may realize the electrical connection of a plurality of substrates through the electrical connection structure 100a. In addition, the electronic device 10 of the embodiment may be provided with any electrical connection structure (i.e., any one of the electrical connection structures 100a to 100i) in the above-mentioned specification. In some embodiments, a plurality of electrical connection structures may be provided in the electronic device 10, where the electrical connection structures may be provided with any one of the electrical connection structures in the above specification or a combination of the above electrical connection structures, but the disclosure is not limited thereto. Here, the electronic device 10 of the embodiment may include a display device, an antenna device, a sensing device, a light-emitting device, a touch display device, a packaging device, a curved display, a free-form display, or a splicing device, but the disclosure is not limited thereto. The electronic device 10 may include a bendable or flexible electronic device. The electronic device 10 may include a plurality of light boards electrically connected to each other. The electronic device 10 includes, for example, a liquid crystal layer or light emitting diodes (LED). The electronic component 20 may include passive components and active components, such as capacitors, resistors, inductors, variable capacitors, filters, diodes, transistors, inductors, MEMS, liquid crystal chips, etc., but the disclosure is not limited thereto. The diodes may include light emitting diodes or photodiodes. The light emitting diodes may include, for example, organic light emitting diodes (OLEDs), mini LEDs, micro LEDs, quantum dot LEDs, fluorescence, phosphor or other suitable materials, or a combination thereof, but the disclosure is not limited thereto. The sensors may include, for example, capacitive sensors, optical sensors, electromagnetic sensors, fingerprint sensors (FPS), touch sensors, antennas, or styluses (pen sensors), etc., but the disclosure is not limited thereto. The antenna is, but not limited to, a liquid crystal antenna, a diode antenna. An antenna device may include, but is not limited to, an antenna splicing device. It should be noted that, the electronic device 10 may be any arrangement and combination of the above, but the disclosure is not limited thereto. In addition, the electronic device 10 may have a rectangular shape, a circular shape, a polygonal shape, a shape with curved edges, or other suitable shapes in appearance. The electronic device 10 may have peripheral systems such as a driving system, a control system, a light source system, a shelf system, etc., to support a display device, an antenna device or a splicing device.

It should be noted that, in the above-mentioned embodiments, the number of electrical connection structures is schematically shown as one, and the number of substrates is schematically shown as two or three, but the disclosure is not limited thereto. In other not-shown embodiments, the number of electrical connection structures and the number of substrates may be increased according to actual requirements, which still fall within the scope of the disclosure. Moreover, the electrical connection structure may be selected from any one of the electrical connection structures in the above-mentioned specification or a combination of the above-mentioned electrical connection structures, but the disclosure is not limited thereto.

In summary, in the embodiments of the disclosure, the through hole penetrates the first substrate and exposes a part of the second upper surface of the second conductive pad, and the conductive material is partially disposed in the through hole, so that the first substrate and the second substrate may be electrically conducted. Therefore, the electrical connection structure of the disclosure may achieve the effect of electrically connecting a plurality of substrates, and when it is subsequently applied to an electronic device, the electrical conduction path between the substrates may be shortened and a design of a peripheral region of the substrate may be simplified, so as to achieve a slim border design or even no border design of the electronic device. In addition, the conductive material includes the narrowest portion and the first contact portion in contact with the second upper surface. In a cross-sectional view, the length of the first contact portion is greater than the length of the narrowest portion, which increases a contact length between the conductive pad and the conductive material, and enhances a success rate of electrical connection of multiple substrates, so that the electrical connection structure of the disclosure may have better electrical reliability.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. An electrical connection structure, comprising:
a first substrate;
a first conductive pad, disposed on the first substrate, wherein the first conductive pad comprises a first upper surface;
a second substrate;
a second conductive pad, disposed on the second substrate, wherein the second conductive pad comprises a second upper surface;
a through hole, penetrating the first substrate and exposing a part of the second upper surface; and
a conductive material, partially disposed in the through hole, wherein the conductive material comprises a narrowest portion and a first contact portion in contact with the second upper surface, and a length of the first contact portion is greater than a length of the narrowest portion in a cross-sectional view.

2. The electrical connection structure according to claim 1, wherein the conductive material comprises a second contact portion in contact with the first upper surface, and a length of the second contact portion is greater than the length of the narrowest portion.

3. The electrical connection structure according to claim 1, wherein the conductive material comprises a second contact portion in contact with the first upper surface, a length of the second contact portion is greater than the length of the first contact portion, and the length of the first contact portion is greater than the length of the narrowest portion.

4. The electrical connection structure according to claim 2, wherein the first conductive pad comprises a side surface adjacent to the through hole, and the conductive material is in contact with the side surface and the second contact portion.

5. The electrical connection structure according to claim 4, wherein an air gap is between the conductive material and the through hole.

6. The electrical connection structure according to claim 1, wherein the through hole comprises at least one through hole wide portion, and the conductive material fills the at least one through hole wide portion.

7. The electrical connection structure according to claim 1, further comprising:
an intermediate layer, disposed between the first substrate and the second substrate, and covering the second conductive pad, wherein the through hole penetrates the first substrate and a part of the intermediate layer to expose a part of the second upper surface.

8. The electrical connection structure according to claim 7, wherein a material of the intermediate layer comprises an organic material, an inorganic material, or a combination thereof.

9. The electrical connection structure according to claim 1, wherein a diameter of the through hole first gradually decreases and then gradually increases in a direction from the first substrate toward the second upper surface.

10. The electrical connection structure according to claim 1, wherein a diameter of the through hole gradually increases in a direction from the first substrate toward the second upper surface.

11. The electrical connection structure according to claim 1, wherein the through hole comprises a stepped through hole.

12. The electrical connection structure according to claim 1, wherein the conductive material has an arc-shaped upper surface.

13. The electrical connection structure according to claim 1, wherein the first substrate comprises a base layer and a dielectric layer, the dielectric layer is disposed on the base layer, and the first conductive pad is disposed on the dielectric layer.

14. The electrical connection structure according to claim 13, wherein a material of the base layer comprises a polymer, and a material of the dielectric layer comprises an inorganic material.

15. The electrical connection structure according to claim 1, wherein the conductive material comprises a second contact portion in contact with the first upper surface, and the length of the first contact portion is greater than a length of the second contact portion.

16. The electrical connection structure according to claim 1, wherein a material of the conductive material comprises tantalum (Ta), niobium (Nb), hafnium (HO, nickel (Ni), chromium (Cr), cobalt (Co), zirconium (Zr), tungsten (W), aluminum (Al), tin (Sn), copper (Cu), silver (Ag), aurum (Au), or an alloy or a combination thereof.

17. The electrical connection structure according to claim 1, wherein a material of the first substrate comprises glass, quartz, sapphire, ceramic, polycarbonate (PC), polyimide (PI), polyethylene terephthalate (PET), or a combination thereof.

18. The electrical connection structure according to claim 1, wherein a material of the second substrate comprises glass, quartz, sapphire, ceramic, polycarbonate (PC), polyimide (PI), polyethylene terephthalate (PET), or a combination thereof.

19. An electronic device, comprising:
an electrical connection structure, comprising:
a first substrate;
a first conductive pad, disposed on the first substrate, wherein the first conductive pad comprises a first upper surface;
a second substrate;
a second conductive pad, disposed on the second substrate, wherein the second conductive pad comprises a second upper surface;
a through hole, penetrating the first substrate and exposing a part of the second upper surface; and
a conductive material, partially disposed in the through hole, wherein the conductive material comprises a narrowest portion and a first contact portion in contact with the second upper surface, and a length of the first contact portion is greater than a length of the narrowest portion in a cross-sectional view;
an electronic component, disposed on the first substrate, and electrically connected to the first conductive pad disposed on the first substrate;
a driving substrate; and
a third conductive pad, disposed on the driving substrate, and electrically connected to the second substrate.

20. The electronic device according to claim 19, wherein the second substrate comprises a conductive via, and the third conductive pad is electrically connected to the conductive via of the second substrate.
